(19) United States
(12) Patent Application Publication
(10) Pub. No.: US 2020/0234955 A1
(43) Pub. Date: Jul. 23, 2020

(54) DIRECT-STRUCTURABLE FORMULATIONS BASED ON METAL OXIDE PRECURSORS FOR PRODUCING OXIDIC LAYERS

(71) Applicant: Evonik Operations GmbH, Essen (DE)

(72) Inventors: Alexey Merkulov, Marl (DE); Jochen Brendt, Regensburg (DE); Jonas Köhling, Bremen (DE)

(73) Assignee: Evonik Operations GmbH, Essen (DE)

(21) Appl. No.: 16/483,056

(22) PCT Filed: Jan. 25, 2018
(86) PCT No.: PCT/EP2018/051798

§ 371 Date: Aug. 2, 2019

(30) Foreign Application Priority Data
Feb. 8, 2017 (EP) 17155205.2

(51) Int. Cl. H01L 21/02; C09D 1/00; C09D 5/24; C01G 15/00; C01F 17/218; C01G 17/02; C01G 19/02; C01G 9/02; H01L 29/24; H01L 29/786

(52) U.S. Cl. CPC H01L 21/02628; C09D 1/00; C09D 5/24; C01G 15/00; C01F 17/218; C01P 2006/40; C01G 19/02; C01G 9/02; H01L 21/02565; H01L 29/24; H01L 29/7869; C01G 17/02

(57) ABSTRACT

The invention relates to direct-structurable coating compositions comprising a metal oxide precursor, a photoacid generator, and a solvent. The present invention also relates to the use of such a coating composition to produce directly structured metal oxide layers, a method for producing metal oxide layers using such a coating composition, a metal oxide-containing layer produced according to such a method, and the use of such a metal oxide-containing layer to produce electronic components, in particular to produce transistors, diodes, sensors or solar cells.

### CROSS REFERENCE TO RELATED APPLICATIONS

This application is a 35 U.S.C. § 371 U.S. national phase entry of International Application No. PCT/EP2018/051798 having an international filing date of Jan. 25, 2018, which claims the benefit of European Application No. 17155205.2 filed Feb. 8, 2017, each of which is incorporated herein by reference in its entirety.

### FIELD

The present invention provides directly structurable coating compositions comprising a metal oxide precursor, a photoacid generator and a solvent. The present invention further relates to the use of such a coating composition for production of directly structured metal oxide layers, to a method for producing metal oxide layers using such a coating composition, to a metal oxide-containing layer produced by such a method, and to the use of such a metal oxide-containing layer for production of electronic components, especially for production of transistors, diodes, sensors or solar cells.

### BACKGROUND

Metal oxide layers are essential for many applications, particularly within the sector of semiconductor technology. Metal oxide layers can be applied by various methods to a variety of surfaces. These methods include vacuum methods (sputtering, chemical vapor deposition) and wet-chemical methods. Of these, the wet-chemical methods, also referred to as liquid-phase methods, have the advantage that they require less, and less complex, apparatus. Liquid-phase methods may be carried out with dispersed nanoparticles or with precursor systems. Dispersed nanoparticles have the disadvantage here that their preparation involves considerable apparatus and that the semiconductor layers produced using them often have adverse properties.

For this reason, preference is often given to liquid-phase coating methods which employ precursors. A metal oxide precursor is a compound which can be decomposed thermally or with electromagnetic radiation and with which layers containing metal oxide can be formed in the presence or absence of oxygen or other oxidizing agents.

Metal oxide-containing layers formed from metal oxide precursors, which are of interest for a variety of applications in semiconductor technology, are typically structured through the use of photoresists, which result in an increased requirement for materials, a multitude of additional process steps and additional stress on the oxide layer resulting from contact with aggressive materials.

The direct structuring of metal oxide-containing layers is making the use of photoresists obsolete. The prior art discloses four different methods for the direct structuring of metal oxide-containing layers. A first method (Cordonier et al., Langmuir, 2011, 27 (6), p. 3157-3165) comprises the use of photoacid-generating ligands for indium oxide precursors and titanium oxide precursors based on catechol. The photoinduced cleavage of the ligand releases an acid molecule, which brings about a difference in solubility in the exposed region compared to the rest of the layer that enables development as a positive resist. The method described is greatly restricted from a practical point of view by the necessity of having to synthesize ligands appropriate for the metal oxide precursor used in each case.

A second method (Rim et al., ACS Nano, 2014, 8 (9), p. 9680-9686) describes formulations based on metal nitrates which can be utilized for the production of metal oxide-containing layers and can be structured directly by addition of ammonium hydroxide and acetylacetone. The principle of action is based on the binding of acetylacetonate to the metal centre, which gives rise to a photosensitive metal complex. Irradiation initiates a polymerization that brings about a difference in solubility compared to the unexposed, non-polymerized region of the coating (negative resist). The usability of metal oxide precursors is greatly limited in this method by the necessity of a ligand exchange with acetylacetone.

A further method (JP 07258866 A) describes a formulation which enables direct structuring by addition of water-releasing molecules and, optionally, photoacid generators. Polycondensation, which is initiated by prior release of water (and optionally acid molecules), brings about a difference in solubility in exposed and unexposed regions (negative resist). In this method, it is possible to use exclusively metal oxide precursors crosslinkable via polycondensation reactions.

A last method known in the prior art for the direct structuring of metal oxide-containing layers (DE 102013212018 A1) describes metal oxide precursors having a photocrosslinkable ligand and a non-photocrosslinkable ligand. A difference in solubility between exposed and unexposed regions of the coating is brought about by polymerization of the ligands (negative resist). A limiting factor for corresponding methods is the metal oxide precursors, which have to be synthesized in a controlled manner by ligand exchange with polymerizable ligands, for example methacrylic acid.

### SUMMARY

The problem addressed by the present invention is thus that of providing a coating composition capable of overcoming the disadvantages present in the prior art.

This problem is solved in the present context by a coating composition comprising:
a) at least one metal oxide precursor,
b) at least one photoacid generator and
c) at least one solvent.

In a further aspect, the present invention is also directed to the use of the coating composition as described herein for production of structured metal oxide layers.

### DETAILED DESCRIPTION

In a further aspect, the present invention is also directed to a method for producing metal oxide layers, characterized in that the method comprises the following steps:
(I) coating a substrate with at least one coating composition as described herein;
(II) exposing the coating thus applied;
(III) developing the coating.

In another aspect, the present invention is directed to a metal oxide-containing layer that has been produced by a method as described herein.

In a last aspect, the present invention, finally, is directed to the use of a metal oxide-containing layer produced as described herein for production of electronic components, especially for production of transistors, diodes, sensors or solar cells.

Further aspects can be inferred from the appended claims.

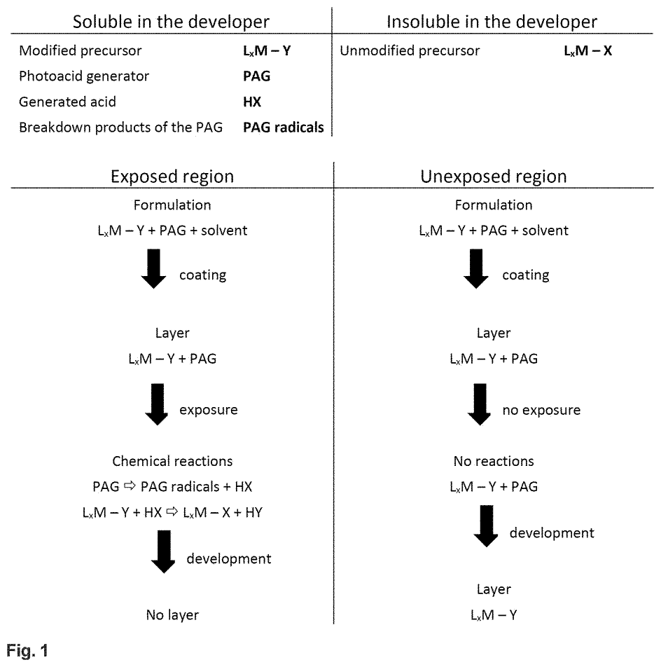

FIG. 1 shows the principle of action of the coating composition according to the invention, shown in schematic, simplified form. Compared one beside the other are a region of the substrate to be coated which is exposed in the course of the method for producing a metal oxide layer as described herein, and a region of the substrate which is not exposed. Both regions are first coated with the coating formulation according to the invention. The coating thus produced comprises the metal oxide precursor (“LₓM-X”) and the photoacid generator (PAG). In the course of the partial exposure, there is photolytic breakdown of the photoacid generator to an acid molecule (HX) and the radicals (PAG radicals). The acid molecules that have thus been released in the exposed region react with the metal oxide precursor and form developer-soluble modified precursor (“LₓM-Y”) and ligand exchange product (“HY”). No acid molecules are released in the unexposed region. In this way, a difference in solubility of the coating applied is brought about. In the course of the development, all constituents that are soluble in the developer solution are removed. This results in removal of the entire coating in the exposed region, but only in removal of the photoacid generator in the unexposed region. The result is surface structuring forming a pattern in the manner of a positive resist.

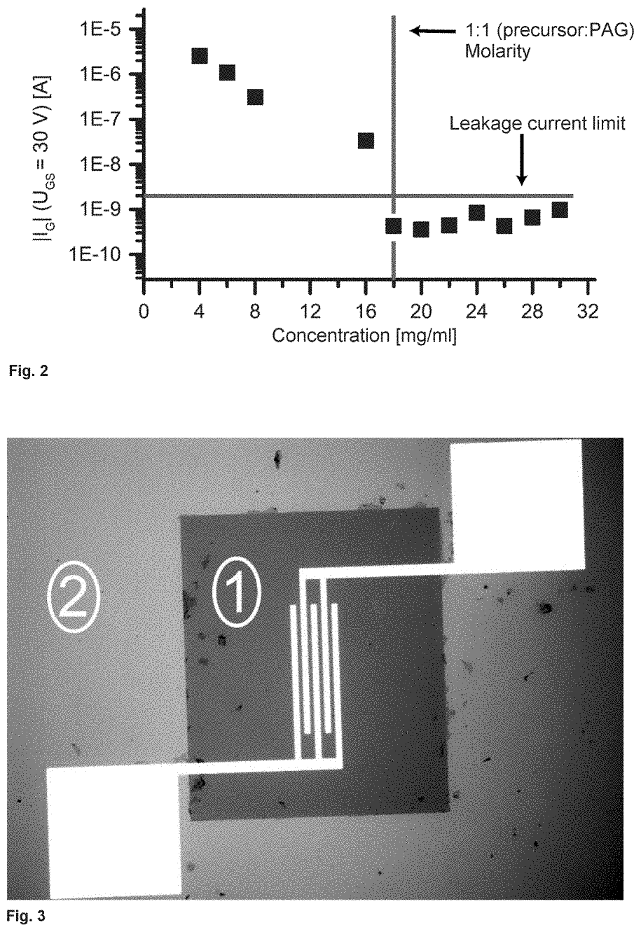

FIG. 2 shows leakage currents for various coating composition formulations having different concentrations of photoacid generator. It becomes clear that those formulations containing the photoacid generator in at least an equimolar ratio to the metal oxide precursor achieve improved results with regard to leakage currents that occur.

FIG. 3 shows a light microscope image of a 7 nm-thick directly structured semiconductor layer in a TFT (thin-film transistor) structure. (1) semiconductor layer; (2) substrate.

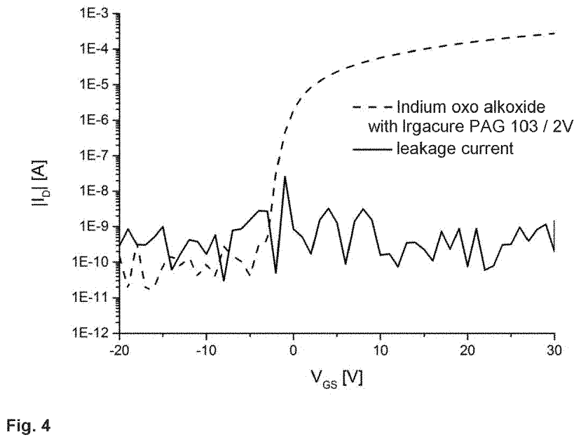

FIG. 4 shows a transfer characteristic for the semiconductor layer directly structured in Working Example 1 of the present invention, showing a reference and the leakage current.

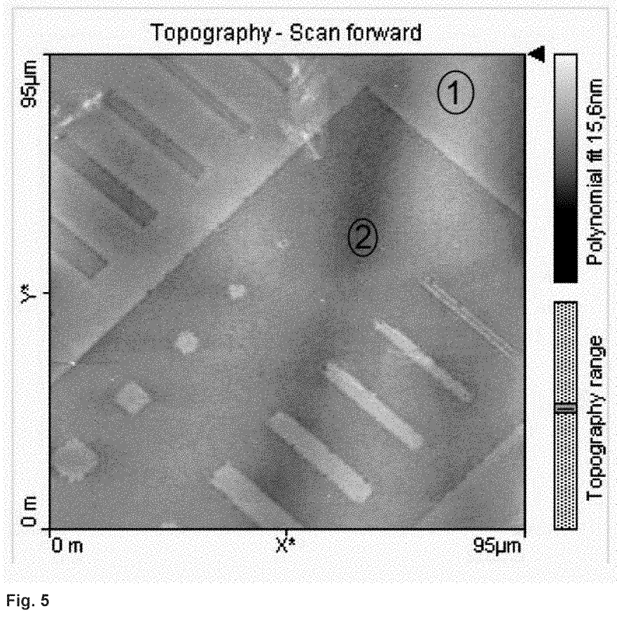

FIG. 5 shows an AFM measurement of a 7 nm-thick directly structured layer. (1) semiconductor layer; (2) substrate.

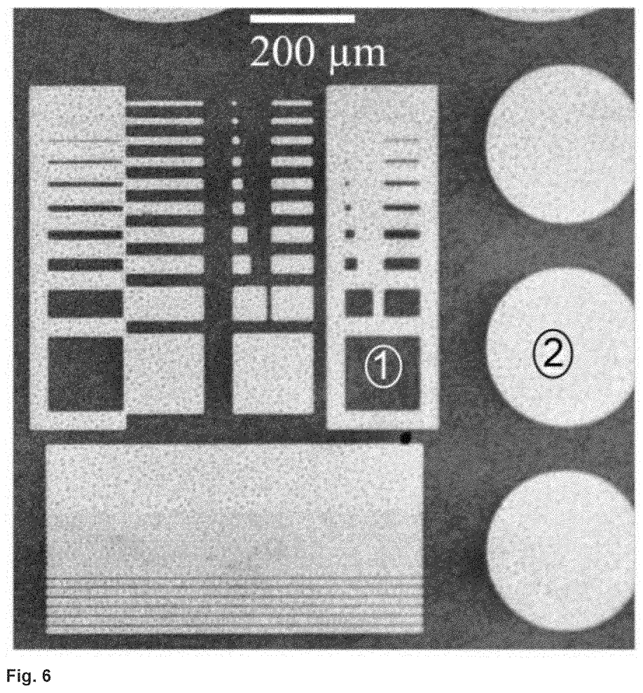

FIG. 6 shows a light microscope image of various structures of a semiconductor layer directly structured in Working Example 1. (1) semiconductor layer; (2) substrate.

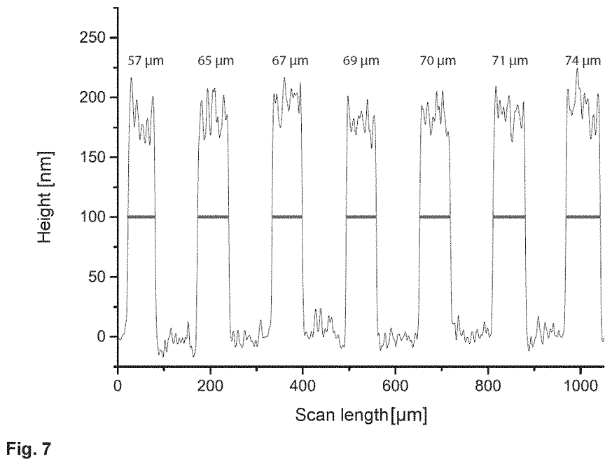

FIG. 7 shows a profilometer measurement of a 200 nm-thick directly structured semiconductor layer.

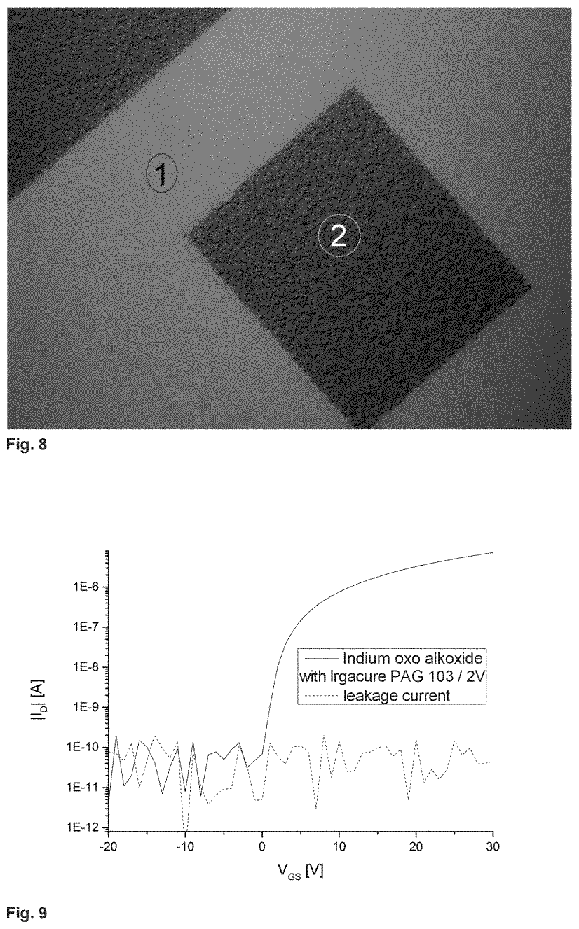

FIG. 8 shows a light microscope image of the semiconductor layer directly structured in Working Example 2 in a TFT structure. (1) substrate; (2) semiconductor layer.

FIG. 9 shows a transfer characteristic for the semiconductor layer directly structured in Working Example 3.

“At least one” as used herein means 1 or more, i.e. 1, 2, 3, 4, 5, 6, 7, 8, 9 or more. “At least one solvent” thus means, for example, at least one type of solvent, which may mean one type of solvent or a mixture of two or more different solvents.

“About” as used herein means a region of +/−10%, preferably +/−5%, of the value reported in each case.

It is a feature of the coating compositions according to the invention that at least one metal oxide precursor and at least one photoacid generator are formulated together in direct combination as individual components of the composition. According to the present invention, the at least one photoacid generator is not a ligand of the metal oxide precursor, meaning that there is no bond between the photoacid generator molecule and the metal oxide precursor at any time within the method sequence. Both components are present dissolved in one or more suitable solvents. Such a simple combination of a precursor and a photoacid generator obviates the need for a complex synthesis of suitable ligands and the corresponding metal complexes. The formulations according to the invention can thus be matched to the respective application in a correspondingly simpler and more specific manner. Furthermore, for the development of the structures, it is possible to use a multitude of developer solvents. It is also possible to use water-sensitive substances since it is possible to avoid aqueous solutions.

This results in the following advantages over the prior art:
Precursors that are already known can be used unchanged. Complex synthesis of specific ligands and metal complexes is dispensed with. The precursors do not need to be hydrolytically polymerizable, nor does ligand exchange with acetylacetone have to be possible.
It is possible via the choice of photoacid generator to specifically choose the wavelength range to which the formulation is sensitive.
This enables universal use via a variety of possible combinations between precursor and photoacid generator (and developer).
Direct structuring of this formulation is possible with few method steps, which means that time as well as resources can be saved and there is an increase in method reliability.

The present invention therefore first provides a coating composition comprising at least one metal oxide precursor, at least one photoacid generator and at least one solvent. The composition as described herein is characterized in that the at least one metal oxide precursor and the at least one photoacid generator are not bonded to one another.

In one embodiment, it is a feature of the coating composition according to the invention that the metal oxide precursor comprises at least one metal atom selected from the group consisting of In, Zn, Ga, Y, Sn, Ge, Sc, Ti, Zr, Al, W, Mo, Ni, Cr, Fe, Hf and Cu. In preferred embodiments, the at least one metal oxide precursor comprises at least one metal selected from the group consisting of In, Ga, Ge, Sn, Y and Zn.

In the context of the present invention, a “metal atom” correspondingly refers either to a metal atom or to a semimetal atom. The same applies in respect of the “metal oxides”, and “metal oxide-containing layers” which can be produced using them.

In one embodiment, it is a further feature of the coating composition according to the invention that the at least one metal oxide precursor comprises at least one ligand selected from the group consisting of oxo radicals, hydroxyl radicals, alkoxy radicals, carboxyl radicals, β-diketonate radicals, halide radicals, nitrate radicals and secondary and primary amine radicals.

A first advantage of the coating compositions as described herein and the use thereof is that it is possible to use metal oxide precursors that are already known in the prior art and are used in a familiar manner.

In the context of the present invention, it is advantageously possible to use, for example, without restriction, especially metal oxide precursors selected from the group consisting of [In₆O(OMe)₁₂Cl₆][NH₂Me₂]₂(MeOH)₂, Ga(acac)₃, Y₅O(OⁱPr)₁₃, Ge(OⁱPr)₄, In(NO₃)₃, InCl₃, Sn(O^{t}Bu)₄ and Zn(acac)₂.

There are generally no particular limitations in respect of the metal oxide precursors usable in the context of the present invention, provided that they have at least one ligand which can be modified by the precursor compound via an acidic elimination. In this way, a difference in solubility between an intact metal oxide precursor coating and a non-intact, i.e. acidically cleaved, metal oxide precursor coating can be brought about.

The aforementioned effect is brought about in accordance with the invention through the use of at least one photoacid generator in the coating composition as described herein. In the context of the present invention, a photoacid generator is a compound which releases one or more acid molecules under the action of electromagnetic radiation, especially UV light. According to the present invention, such an acid molecule may be an organic or inorganic (mineral) acid. Examples of organic acids include but are not limited to carboxylic acids, sulfonic acids and phosphonic acids. Examples of mineral acids include but are not limited to hydrochloric acid, hydrofluoric acid, phosphoric acid, sulfuric acid and nitric acid. The term “acid molecule” in the context of the present further includes inorganic salts which form mineral acid molecules in protic solution. In this connection, examples include, without restriction, PF₄⁻ and BF₄⁻.

In one embodiment, it is consequently a feature of the coating composition as described herein that the at least one photoacid generator is capable of releasing acid molecules under the action of electromagnetic radiation. A photoacid generator according to the present invention may be an ionic or nonionic compound.

Generally suitable in the context of the present invention are all photoacid generators which fulfil the aforementioned criteria. Examples in this connection, without restriction, especially include photoacid generators selected from the group consisting of (Z)-[2-(propylsulfonyloxyimino)-3-thienylidene](o-tolyl)acetonitrile), triphenylsulfonium triflate, diphenyliodonium nitrate, 1-hydroxycyclohexyl phenyl ketone, 2-hydroxy-2-methyl-1-phenyl-1-propanone, 2-hydroxy-1-[4-(2-hydroxyethoxy)phenyl]-2-methyl-1-propanone, methyl benzoylformate, 2-[2-oxo-2-phenylacetoxyethoxy]ethyl oxyphenylacetate, 2-[2-hydroxyethoxy]ethyl oxyphenylacetate, 2,2-dimethoxy-2-phenyl acetophenone, 2-benzyl-2-(dimethylamino)-1-[4-(4-morpholinyl)phenyl]-1-butanone, 2-methyl-1-[4-(methylthio)phenyl]-2-(4-morpholinyl)-1-propanone, diphenyl(2,4,6-trimethylbenzoyl)phosphine oxide, bis(2,4,6-trimethylbenzoyl)phenylphosphine oxide and mixtures of the above. In general terms, all commercially available photoacid generators that are known in the prior art are suitable for use in coating compositions according to the present invention.

The principle of action of the coating formulations according to the invention is based on the photoinduced elimination of one or more acid molecules by at least one photoacid generator. According to the present invention, photoacid generator and metal oxide precursor are formulated in combination with one another in the coating composition according to the invention, but are not bonded to one another, i.e. are present as separate molecules in the coating composition. After the coating composition has been applied to the surface to be coated, acid molecules detached in the course of a subsequently conducted exposure react with the metal oxide precursors present in the coating applied, but exclusively in the exposed region. The action of the acid molecules on the metal oxide precursor brings about a difference in solubility between exposed and unexposed regions of the coating applied, with a significant increase in the solubility in exposed regions compared to the solubility in unexposed regions. A significant difference in the solubility of the coating applied in exposed and unexposed regions is brought about according to the present invention when the coating in the exposed region can be completely dissolved and removed under the action of a developer solution, but the coating in the unexposed region remains intact under the action of the same developer solution. In this way, direct structuring of the coating surface is possible according to the present invention. According to the present invention, the coating pattern achieved in the course of direct structuring according to the invention corresponds to a positive resist.

Solvents suitable for use in the coating compositions as described herein are preferably selected from the group consisting of β-diketones, ether alcohols and derivatives thereof such as esters, alcohols, ethers and esters, nitriles. According to the present invention, the coating composition according to the invention may comprise a single solvent or a mixture of two or more solvents. Particularly suitable examples in the context of the present invention of usable solvents include, although this should not be regarded as a restriction, N-methyl-2-pyrrolidone, ethanol, methanol, 2-propanol, 1-butanol, 1-cyclohexanol, 1-methoxy-2-propanol, 2-ethoxyethanol, 2-butoxyethanol, 2-(2-methoxyethoxy)ethanol, ethyl lactate, butyl lactate, tetrahydrofurfuryl alcohol, acetylacetone, ethyl acetate, acetonitrile and acetylacetone.

In some embodiments, coating compositions according to the invention contain the at least one metal oxide precursor, as defined above, in bulk concentrations of about 5 mg/ml to about 50 mg/ml, preferably about 5 mg/ml to about 30 mg/ml, especially about 5 mg/ml to about 25 mg/ml, most preferably about 7 mg/ml to about 25 mg/ml. It will be appreciated that, depending on the nature of the metal oxide precursor to be used in each case, different concentration ranges within which the desired coating can be advantageously generated may arise.

In some embodiments, coating composition according to the invention contain the at least one photoacid generator, as defined above, in bulk concentrations of about 1 mg/ml to about 60 mg/ml, preferably about 1.5 mg/ml to about 55 mg/ml, especially about 2 mg/ml to about 55 mg/ml.

In some embodiments, the at least one metal oxide precursor and the at least one photoacid generator are used in such a molar ratio that the at least one photoacid generator, based on the acid molecules releasable under the action of electromagnetic radiation, is present in at least an equimolar ratio to the at least one metal oxide precursor in the composition as described herein. For instance, for a photoacid generator that releases one mole of acid molecules per mole of photoacid generator molecules and is present in the coating composition in a concentration of 10 mol/l, there is a resultant concentration of 10 mol/l for the respective metal oxide precursor. For a photoacid generator that, by contrast, releases two moles of acid molecules per mole of photoacid generator molecules, given a concentration of 10 mol/l, there is a resultant concentration of 20 mol/l for the respective metal oxide precursor.

In some embodiments, the at least one metal oxide precursor and the at least one photoacid generator are used in such a molar ratio that the at least one photoacid generator, based on the acid molecules releasable under the action of electromagnetic radiation, is present in an equimolar ratio to the at least one metal oxide precursor in the composition as described herein.

In some embodiments of the present invention, a coating composition as described herein, as well as the at least one metal oxide precursor, the at least one photoacid generator and the at least one solvent, may comprise further additives. In general, all commonly used additives for coating compositions for production of metal oxide layers are suitable. In this connection, reference is made by way of example, without restriction, to surfactants and foam inhibitors.

The present invention further provides for the use of the coating composition as described herein for production of directly structured metal oxide layers.

In addition, the present invention is also directed to a method for producing metal oxide layers. According to the present invention, the production method comprises the following steps:

In a first step (step (I)) of the method according to the invention, a substrate is coated with at least one coating composition as described herein. Suitable coating methods may, for example, without restriction, be selected from the group consisting of printing methods, spraying methods, rotary coating methods, dipping methods and methods selected from meniscus coating, slit coating, slot-die coating and curtain coating. Production methods according to the invention may comprise one or more coating steps conducted successively one after another, as defined below. By repeated application, coatings with elevated layer thickness can be achieved.

In order to improve the coating quality, it is possible at this point to conduct an optional thermal treatment as known from the prior art for photoresists. A treatment at the temperatures between 50° C. and 150° C. for the period between 10 sec and 5 min can improve the layer contrast.

In a step that follows the coating (step (II)), the coating thus applied is exposed. The exposure can be effected by means of familiar methods known for this purpose in the prior art. In some embodiments, it is a feature of the production method according to the invention that the exposure is effected by means of irradiation with UV, IR or VIS radiation. Particularly suitable in this connection are exposure methods in which electromagnetic radiation can act on the regions of the coating to be exposed through a suitable exposure mask by means of halogen lamps, low-pressure mercury vapor lamps, especially low-pressure quartz glass mercury lamps, or via an excimer. The duration, radiation dose and wavelength are chosen and adjusted here depending on the particular photoacid generator used. With regard to the particular metal oxide precursor used in the coating composition, there is no dependence with regard to irradiation time, dose and wavelength of the exposure step.

In some embodiments, the electromagnetic irradiation effected in step (II) is effected here with radiation of a wavelength in the region of λ=100-500 nm.

In some embodiments, the electromagnetic irradiation effected in step (II) is effected over a period of about 10 seconds to about 5 minutes, preferably about 10 seconds to about 3 minutes, especially about 10 seconds to about 120 seconds.

In some embodiments, it is a further feature of the method according to the invention that the photoacid generator in the coating composition releases acid molecules that alter the solubility of the coating in the course of the exposure in step (II), as elucidated above.

In order to improve the effect of the acid molecules, it is possible at this point to conduct an optional thermal treatment as known from the prior art for photoresists. A treatment at the temperatures between 50° C. and 150° C. for the period between 10 sec and 5 min can improve the layer contrast.

In a next step (step (III)) that follows the exposure, the coating is developed. According to the present invention, the development is effected by treating the coating with a developer solution. In some embodiments, the development is effected by treatment with at least one solvent selected from the group consisting of aqueous bases, aqueous acids, water, alcohols, glycols, ketones, esters and mixtures of the above. In some embodiments, the developer solution is selected from the group consisting of ethanol, propanol, 1-methoxy-2-propanol and mixtures of the above. Preferably, the developer solution to be used in step (III) of the method according to the invention is ethanol, dimethyl succinate, ethylene glycol and DMSO.

In some embodiments, it is a further feature of the production method according to the invention that the method also includes a step of thermal conversion (treatment) of the developed coating (step IV). A thermal conversion according to step (IV) is preferably effected at temperatures greater than 300° C., especially at 350° C. The duration of such a thermal conversion, in some embodiments, is in the range from about 30 minutes to about 90 minutes, for example 60 minutes.

Likewise possible is a conversion by an electromagnetic irradiation. Suitable electromagnetic conversion methods and parameters are known in the prior art and are guided by the type of the respective metal oxide layer.

In some embodiments, the conversion of the coating is effected in the presence of oxygen and/or other oxidizing agents, but preferably in the presence of oxygen.

The present invention additionally also provides a metal oxide-containing layer that has been produced by a process as described herein.

In a last aspect, finally, the present invention is also directed to the use of at least one such metal oxide-containing layer for production of electronic components, especially for production of transistors, especially thin-film transistors (TFTs), diodes, sensors or solar cells. TFTs can be used advantageously for the active scattering of pixels in LCDs. Another application is that of switching circuits composed of TFTs, for the purpose of realizing RFID tags, for example.

All the documents cited are incorporated by reference herein in their entirety. Further embodiments can be found in the examples which follow, but the invention is not limited ere 0.

It will be apparent and is the intention that all embodiments disclosed herein in connection with the compounds described are equally applicable to the uses and methods described, and vice versa. Such embodiments therefore likewise fall within the scope of the present invention.

The examples which follow are intended to elucidate the subject-matter of the present invention in detail, without having any limiting effect.

### EXAMPLES

Production of a coating composition according to the invention: The metal oxide precursor is weighed out in a defined concentration and dissolved in one or more solvents by stirring overnight (optionally by heating). The formulation thus obtained is filtered through a PTFE filter. The photoacid generator selected is weighed out and dissolved in the formulation (optionally with ultrasound) and optionally filtered through a PTFE filter.

### Example 1: Production of an Indium Oxo Alkoxide Coating, Spin-Coating

Semiconductor base, oxime sulfonate (nonionic) as photoacid generator, coated via spin-coating, exposed in a mask aligner and developed with ethanol. After the development, the sample was converted to the semiconductor thermally and via UVO.

Formulation: The precursor used was [In₆O(OMe)₁₂Cl₆][NH₂Me₂]₂(MeOH)₂, the photoacid generator used was (Z)-[2-(propylsulfonyloxyimino)-3-thienylidene](o-tolyl)acetonitrile) (Irgacure® PAG 103), and the solvent used was 1-methoxy-2-propanol/EtOH (3:1). The concentration in relation to the precursor was 25 mg/ml; that of the photoacid generator was 16 mg/ml.

Spin-coating: Volume 100 μl/cm², spin speed 3000 rpm; spin duration 30 s.

Structuring: Exposure time 3 min; ethanol as developer; development time 15 s.

Further processing: UV/O treatment for 10 min; heat treatment at 350° C. for 60 min.

### Example 1b

As Example 1, except that the spin-coating step was conducted seven times rather than once. The thicker layers can be better characterized by light microscope and profilometer.

### Example 1c

As Example 1, except that the concentration for precursor was 50 mg/ml, and for PAG 60 mg/ml.

### Example 2: Production of an Indium Oxo Alkoxide Coating, Spin-Coating

Semiconductor base, triphenylsulfonium triflate (ionic) as photoacid generator, coated via spin-coating, exposed in UVO box and developed with ethanol. After the development, the sample was converted to the semiconductor thermally and via UVO.

Formulation: The precursor used was [In₆O(OMe)₁₂Cl₆][NH₂Me₂]₂(MeOH)₂, the photoacid generator used was triphenylsulfonium triflate (Ph3 S+CF3 SO3-), and the solvent used was 1-methoxy-2-propanol/EtOH (3:1) with 3% by volume of tetrahydrofurfuryl alcohol. The concentration in relation to the precursor was 12.5 mg/ml.

Spin-coating: Volume 100 μl/cm², spin speed 3000 rpm; spin duration 30 s.

Structuring: Exposure time 1 min; ethanol as developer; development time 15 s.

Further processing: UV/O treatment for 10 min; heat treatment at 350° C. for 60 min.

### Example 3: Production of an Indium Alkoxide Coating, Slot-Die Coating

Semiconductor base, oxime sulfonate (nonionic) as photoacid generator, coated via slot-die coating, exposed in the ghi box and developed with ethanol. After the development, the sample was converted to the semiconductor thermally and via UVO. Example 3 is an example of an alternative method to spin-coating-based methods.

Formulation: The precursor used was [In₆O(OMe)₁₂Cl₆][NH₂Me₂]₂(MeOH)₂, the photoacid generator used was Irgacure® PAG 103, and the solvent used was 1-methoxy-2-propanol/EtOH (3:1). The concentration in relation to the precursor was 25 mg/ml.

Slot-die coating: shim 80 μm, coating gap was 100 μm; the thickness of the wet film was 5.5 μm; the coating speed was 16.6 mm/s.

Structuring: Exposure time 3 min; ethanol as developer; development time 15 s.

Further processing: UV/O treatment for 10 min; heat treatment at 360° C. for 60 min.

The electrical characterization was effected after production of a TFT device with a 4156C Precision Semiconductor Parameter Analyzer from Agilent. The samples were analysed at room temperature under a nitrogen atmosphere. The characterization took place after the thermal treatment. This was done by connecting the (pre-structured) gate, source and drain contacts to the device via tungsten measurement tips. A voltage profile between gate electrode and source electrode between −20 and +30 V was run, and the current which flowed between source electrode and drain electrode was recorded. These data can be used to calculate the mobility values as follows:

$${µ}_{lin} = \frac{\partial {I}_{D}}{\partial {V}_{G}} \frac{L}{{WC}_{i} {V}_{D}}$$

$${µ}_{s a t} = \frac{2 L}{W {C}_{i}} {( \frac{\partial ( \sqrt{{I}_{D}} )}{\partial {V}_{G}} )}^{2}$$

where ID and VG are the current between drain and source and the voltage applied at the gate respectively. L and W correspond to the length and width of the channel, and Ci is the dielectric constant of the dielectric. The higher the mobility value, the better the material.

### Example 4

The universality of the invention was verified using different precursors and PAGs. The formulation and processing was conducted analogously to Example 1; the respective concentrations and substances used are listed in Table 1. In these cases, successful structurability was detected merely by optical means using a light microscope.

TABLE 1

| | Precursor | | Precursor |
|---|---|---|---|
| | concentration | PAG | concentration |
| Precursor | [mg/ml] | used | [mg/ml] |
| [In₆O(OMe)₁₂Cl₆][NH₂Me₂]₂(MeOH)₂ | 12.5 | Irgacure ® | 18 |
| | | PAG 103 | |
| [In₆O(OMe)₁₂Cl₆][NH₂Me₂]₂(MeOH)₂ | 25 | Irgacure ® | 36 |
| | | PAG 103 | |
| [In₆O(OMe)₁₂Cl₆][NH₂Me₂]₂(MeOH)₂ | 37.5 | Irgacure ® | 54 |
| | | PAG 103 | |
| [In₆O(OMe)₁₂Cl₆][NH₂Me₂]₂(MeOH)₂ | 12.5 | Irgacure ® | 20.5 |
| | | PAG 121 | |
| [In₆O(OMe)₁₂Cl₆] [NH₂Me₂]₂(MeOH)₂ | 12.5 | Tri-Ph—S⁺, | 21.3 |
| | | triflate | |
| [In₆O(OMe)₁₂Cl₆] [NH₂Me₂]₂(MeOH)₂ | 12.5 | Di-Ph—I⁺, | 18 |
| | | NO₃_{^{−}} | |
| Ga(acac)₃ | 25 | Irgacure ® | 23.7 |
| | | PAG 103 | |
| Y₅O(OⁱPr)₁₃ | 7.5 | Irgacure ® | 2 |
| | | PAG 103 | |
| Ge(ⁱPrO)₄ | 25 | Irgacure ® | 28.2 |
| | | PAG 103 | |
| In(NO₃)₃ | 25 | Irgacure ® | 29.0 |
| | | PAG 103 | |
| InCl₃ | 25 | Irgacure ® | 39.4 |
| | | PAG 103 | |
| Sn(^{t}BuO)₄ | 25 | Irgacure ® | 21.2 |
| | | PAG 103 | |
| Zn(acac)₂ | 25 | Irgacure ® | 33.0 |
| | | PAG 103 | |

1. A coating composition comprising:
a) a metal oxide precursor,
b) a photoacid generator and
c) a solvent.

2. The coating composition according to claim 1, wherein the metal oxide precursor comprises a metal atom selected from the group consisting of In, Zn, Ga, Y, Sn, Ge, Sc, Ti, Zr, Al, W, Mo, Ni, Cr, Fe, Hf and Cu.

3. The coating composition according to claim 1, wherein the metal oxide precursor comprises a ligand selected from the group consisting of oxo radicals, hydroxyl radicals, alkoxy radicals, carboxyl radicals, β-diketonate radicals, halide radicals, nitrate radicals and secondary and primary amine radicals.

4. The coating composition according to claim 1, wherein the photoacid generator releases one or more acid molecules under the action of electromagnetic radiation.

5. The coating composition according to claim 3, wherein the a photoacid generator, with respect to the acid molecules that can be released under the action of electromagnetic radiation, is present in the composition in at least an equimolar ratio relative to the metal oxide precursor.

6. The coating composition according to claim 1, wherein the solvent is selected from the group consisting of β-diketones, ether alcohols, alcohols, ethers and esters.

7. A directly structured metal oxide layer comprising the coating composition according to claim 1.

8. A method for producing metal oxide layers, wherein the method comprises the following steps:
(I) coating a substrate with the coating composition according to claim 1;
(II) exposing the coating thus applied;
(III) developing the coating.

9. The method according to claim 8, wherein the coating of the substrate in step (I) is effected by means of a coating method selected from the group consisting of printing methods, spraying methods, rotary coating methods, dipping methods and methods selected from meniscus coating, slit coating, slot-die coating and curtain coating.

10. The method according to claim 8, wherein the photoacid generator in the coating composition releases acid molecules in the course of the exposure in step (II) that alter the solubility of the coating.

11. The method according to claim 8, wherein the exposure in step (II) is effected by means of irradiation with UV, IR or VIS radiation.

12. The method according to claim 8, wherein the development is effected by treatment with at least one solvent selected from the group consisting of aqueous bases, aqueous acids, water, alcohols, ketones, esters and mixtures of the above.

13. The method according to claim 8, wherein the method further comprises a step (IV) of thermal conversion of the developed coating.

14. A metal oxide-containing layer produced by a method according to claim 8.

15. An electronic component comprising the metal oxide-containing layer according to claim 14.

16. The coating composition according to claim 2, wherein the metal oxide precursor comprises a ligand selected from the group consisting of oxo radicals, hydroxyl radicals, alkoxy radicals, carboxyl radicals, β-diketonate radicals, halide radicals, nitrate radicals and secondary and primary amine radicals.

17. The coating composition according to claim 2, wherein the photoacid generator releases one or more acid molecules under the action of electromagnetic radiation.

18. The coating composition according to claim 3, wherein the photoacid generator releases one or more acid molecules under the action of electromagnetic radiation.

19. The coating composition according to claim 16, wherein the a photoacid generator, with respect to the acid molecules that can be released under the action of electromagnetic radiation, is present in the composition in at least an equimolar ratio relative to the metal oxide precursor.

20. The coating composition according to claim 2, wherein the solvent is selected from the group consisting of β-diketones, ether alcohols, alcohols, ethers and esters.
